(19) United States
(12) Patent Application Publication
(10) Pub. No.: US 2025/0373209 A1
(43) Pub. Date: Dec. 4, 2025

(54) Measuring Power for Amplifier Circuitry

(71) Applicant: Apple Inc., Cupertino, CA (US)

(72) Inventors: Christof Pfannenmüller, Erlangen (DE); Alexander Spielberger, Bamberg (DE); Robert Weigel, Nuremberg (DE)

(21) Appl. No.: 18/680,713

(22) Filed: May 31, 2024

(51) Int. Cl. H03F 1/56; H03F 1/02; H03F 3/24

(52) U.S. Cl. CPC H03F 1/565; H03F 1/0222; H03F 3/245; H03F 2200/451; H03F 2200/462; H03F 2200/465; H03F 2200/471; H03F 2200/78

(57) ABSTRACT

Wireless circuitry is provided that includes an amplifier configured to receive a radio-frequency signal, a measurement circuit coupled to a power supply terminal of the amplifier and configured to output a measured value, and control circuitry configured to adjust one or more components associated with the amplifier based on the measured value output from the measurement circuit. The measurement circuit can include a transformer or a current mirror circuit. The control circuitry can selectively adjust an input matching circuit, an output matching circuit, and/or one or more bias voltages for the amplifier based on the measured value. The control circuitry can switch one or more amplifiers in and out of use depending on the measured value.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver. Power detectors can be used to measure the power level of a power amplifier or a low noise amplifier. It can be challenging to design a satisfactory power detector.

### SUMMARY

An aspect of the disclosure provides wireless circuitry that includes an amplifier configured to receive a radio-frequency signal, a measurement circuit coupled to a power supply terminal of the amplifier and configured to output a measured value, and control circuitry configured to adjust one or more components associated with the amplifier based on the measured value output from the measurement circuit. The control circuitry can be configured to adjust an input matching circuit of the amplifier based on the measured value, adjust an output matching circuit of the amplifier based on the measured value, and/or adjust one or more bias voltages of the amplifier based on the measured value. The one or more components being adjusted by the control circuitry can include a switch coupled to an input of the amplifier and/or a power supply switch coupled to a power supply terminal of the amplifier,

An aspect of the disclosure provides circuitry that includes an input transistor, an input matching circuit coupled to a gate terminal of the input transistor, an inductor coupled in series with the input transistor, a capacitor coupled across the inductor and a current measurement circuit electrically coupled to at least the inductor and configured to produce an output signal for tuning the input matching circuit. The circuitry can further include bias resistors coupled to the gate terminal of the input transistor and configured to receive a bias voltage that is tuned based on the output signal of the current measurement circuit, a cascode transistor having a source terminal coupled to the input transistor, a drain terminal coupled to the inductor and the capacitor, and a gate terminal configured to receive a bias voltage that is tuned based on the output signal of the current measurement circuit, and/or an output matching circuit directly coupled to the inductor and tuned based on the output signal of the current measurement circuit.

An aspect of the disclosure provides circuitry that includes a first amplifier, a second amplifier, a power detector coupled to a power supply terminal of the first amplifier and configured to output a measured value, and control circuitry configured to control the first and second amplifiers based on the measured value output from the power detector. The circuitry can further include an additional power detector coupled to a power supply terminal of the second amplifier and configured to output a measured value that is conveyed to the control circuitry and a switch coupled to an input of the first amplifier and to an input of the second amplifier, where the control circuitry is configured to control the switch based on the measured values output from the power detector and the additional power detector. The circuitry can further include an input matching circuit coupled to an input of the first amplifier and an output matching circuit coupled to an output of the second amplifier. The second amplifier can be coupled to an output of the first amplifier. The first amplifier can have a first input transistor configured to receive a first bias voltage. The second amplifier can have a second input transistor configured to receive a second bias voltage. The control circuitry can be further configured to adjust one or more of the input matching circuit, the output matching circuit, the first bias voltage, and the second bias voltage based on the measured value output from the power detector.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram showing illustrative power detectors coupled to radio-frequency amplifiers in accordance with some embodiments.

FIG. 4 is a diagram of an illustrative power detector configured to measure a supply current of an amplifier in accordance with an embodiment.

FIG. 5 is a diagram plotting measured current versus input power in accordance with some embodiments.

FIG. 6 is a diagram showing how a switch at an amplifier input can be controlled based on measured values in accordance with some embodiments.

FIG. 7 is a diagram showing how a switch at an amplifier input can be controlled, using a comparator, based on measured values in accordance with some embodiments.

FIG. 8 is a diagram showing how one or more switches within an amplifier can be controlled based on measured values in accordance with some embodiments.

FIG. 9 is a diagram showing how a power supply switch of an amplifier can be controlled based on measured values in accordance with some embodiments.

FIG. 10 is a diagram showing how multiple amplifiers can be controlled based on measured values in accordance with some embodiments.

FIG. 11 is a circuit diagram of an amplifier with a transformer-based measurement circuit in accordance with some embodiments.

FIG. 12 is a circuit diagram of an amplifier with a current-mirror-based measurement circuit in accordance with some embodiments.

FIG. 13 is circuit diagram of multi-stage amplifier circuitry with a current-mirror-based measurement circuit in accordance with some embodiments.

### DETAILED DESCRIPTION

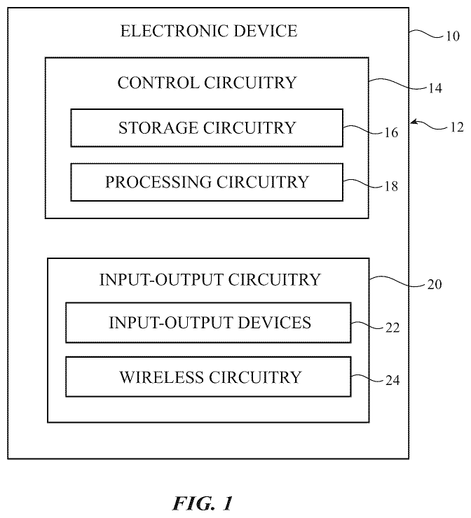

An electronic device such as device 10 of FIG. 1 may be provided with wireless circuitry. Wireless circuitry can include radio-frequency amplifiers such as power amplifiers and low noise amplifiers. Power amplifiers can be used to amplify radio-frequency signals in a transmit path, whereas low noise amplifiers can be used to amplify radio-frequency signals in a receive path. Power detection circuits, sometimes referred to as power detectors, can be coupled one or more radio-frequency amplifiers.

In accordance with some embodiments, a power detector can be configured to monitor or measure a power supply current drawn from an amplifier. Such type of power detector can be referred to as a current measurement circuit or a measurement circuit. The measurement circuit can produce measured values that are analyzed by processing circuitry. The processing circuitry can then adjust, based on the measured values, one or more bias points or a matching circuit of the amplifier. The processing circuitry can additionally or alternatively control a switch at an input of the amplifier. This input switch can alternatively be adjusted by a comparator based on the measured values.

The measured values can be used to control one or more switches within the amplifier and/or a power supply switch of the amplifier. The measured values can be used to control one or more parallel amplifiers or one or more amplifier stages. The measurement circuit can optionally be implemented as part of the amplifier as a transformer-based measurement circuit or a current-mirrored-based measurement circuit. Wireless circuitry configured and operated in this way can be technically advantageous and beneficial to provide improved linearity and improved noise figure.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHZ, 3G bands, 4G LTE bands, 5G New Radio Frequency Range 1(FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or tremendously high frequency bands, etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

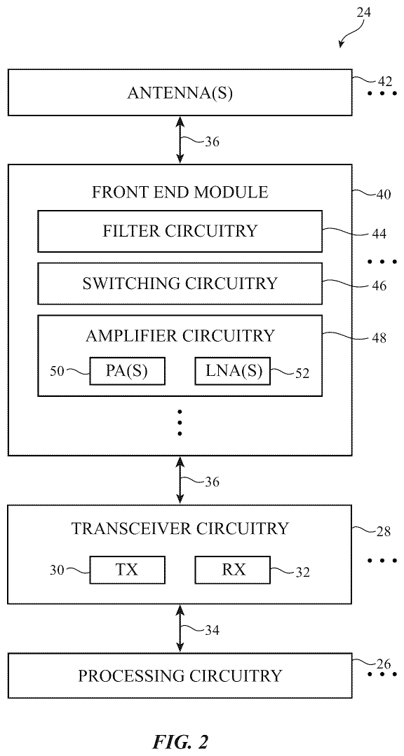

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front end circuitry such as radio-frequency front end module (FEM) 40, and antenna(s) 42. Processing circuitry 26 may include one or more baseband processor, application processor, general purpose processor, microprocessor, microcontroller, digital signal processor, host processor, application specific signal processing hardware, or other type of processor. Processing circuitry 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide transmit signals (e.g., digital or baseband signals) to transceiver 28 over path 34. Transceiver 28 may further include circuitry for converting the transmit (baseband) signals received from processing circuitry 26. For example, transceiver circuitry 28 may include mixer circuitry for up-converting (or modulating) the transmit (baseband) signals to radio frequencies prior to transmission over antenna 42. The example of FIG. 2 in which processing circuitry 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processing circuitry 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), signal attenuators, impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near- field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, radio transceiver circuitry that handles unlicensed radio bands reserved for industrial, scientific, and medical (ISM) purposes, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

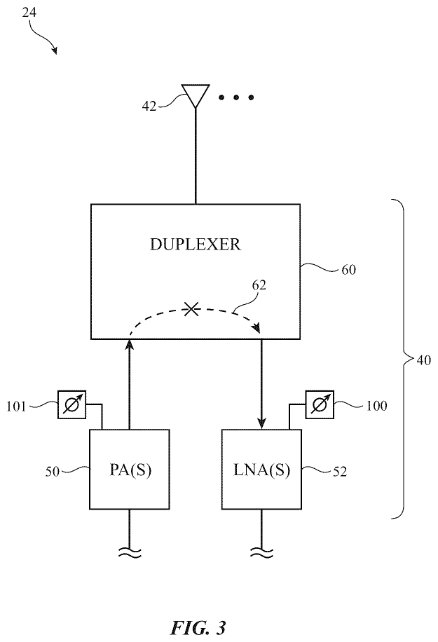

FIG. 3 is a diagram showing radio-frequency amplifiers being coupled to one or more antennas 42 via a duplexing circuit such as duplexer 60. Duplexer 60 can be a phase balanced duplexer (PBD), a Wheatstone balanced duplexer (WBD), a double balanced duplexer (DBD), a circular balanced duplexer (CBD), a tunable duplexer, or other types of duplexing circuit. As shown in FIG. 3, duplexer 60 may be coupled to one or more antennas 42, one or more power (transmitting) amplifiers(s) 50, and one or more low noise (receiving) amplifier(s) 52. Duplexer 60, amplifier 50, and amplifier 52 can be considered part of front end module 40. Duplexer 60 may be a type of radio-frequency filter configured to provide isolation between the transmit path and the receive path (e.g., to prevent signals from the transmit path from leaking or interfering with signals in the receive path, as indicated by broken path 62). Duplexer 60 can allow the transmit path and the receive path to share the same antenna 42. Duplexer 60 can be tuned to adjust its operating frequency range (e.g., to operate duplexer 60 in a selected one of a plurality of frequency bands).

In accordance with some embodiments, the radio-frequency amplifiers (e.g., amplifier 50 and/or amplifier 52) can be coupled to one or more power detection circuits. In the example of FIG. 3, amplifier 52 can be coupled to a first power detector 100, whereas amplifier 50 can be coupled to a second power detector 101. Such power detectors can be configured to obtain a measured value that represents or can be used to determine a current operating power level of the amplifier being measured. For example, a power detector (e.g., power detector 100 or 101) can be configured to measure a current of the amplifier and can sometimes be referred to as a current measurement circuit. Current measurement circuits 100 and 101 can be configured to measure a voltage drop, can be implemented using one or more transistors, one or more diodes, can include analog-to-digital converters, and/or can be implemented using other signal measurement architectures. A current measurement circuit can output a measured current value that can be used to estimate an input power level or an output power level of the amplifier. As another example, a power detector (e.g., power detector 100 or 101) can be configured to measure a voltage of the amplifier and can sometimes be referred to as a voltage measurement circuit. A voltage measurement circuit can output a measured voltage value that is used to estimate an input power level or an output power level of the amplifier. These examples are illustrative. In general, an amplifier can be coupled to one or more power detector configured to measure a current, voltage, power, and/or other parameters associated with an amplifier being measured.

Conventionally, a power detector is coupled to an input of a low noise amplifier. Having a power detector coupled at the input of the low noise amplifier can lead to signal loss and can degrade the noise figure of the amplifier.

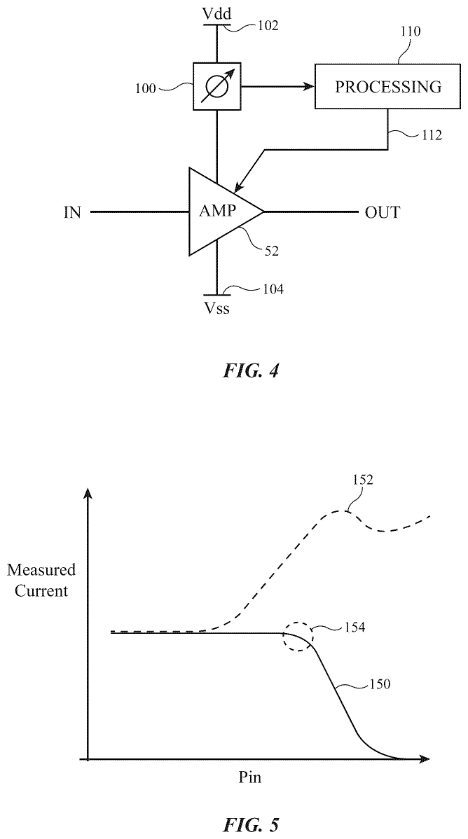

In accordance with an embodiment, power detector 100 may be coupled to a power supply line of amplifier 52 (see, e.g., FIG. 4). As shown in FIG. 4, amplifier 52 may have an input terminal IN, an output terminal OUT, a first power supply terminal coupled to positive power supply line 102 (e.g., a power supply line on which positive power supply voltage Vdd is provided), and a second power supply terminal coupled to ground power supply line 104 (e.g., a ground line on which ground power supply voltage Vss is provided). Power detector 100 may be coupled to the power supply terminal of amplifier 52. Arranged in this way, power detector 100 can be configured to measure an amount of current drawn from the power supply line 102. Power detector 100 is thus sometimes referred to as a current measurement circuit or a measurement circuit. Measurement circuit 100 of this type can produce a measured current value to is related to an operating power level of amplifier 52.

FIG. 5 is a diagram plotting measured current levels versus input power (Pin) of amplifier 52. Measurement circuit 100 can be configured to measure only DC current or both (DC+AC) current flowing through the power supply terminal(s) of amplifier 52. Line 150 plots a relationship between the measured DC-only current and Pin, whereas line 152 plots a relationship between the measured (DC+AC) current and Pin. Region 154 and operating levels to the right of region 154 (e.g., at higher Pin levels) corresponds to amplifier 52 being operated in a saturation mode. The DC measurements should be obtained while amplifier 52 is not operated in the saturation mode. This relationship between the measured current values and Pin (and optionally the output power level Pout) can be determined in advance, so the measured current value(s) output from circuit 100 can be used to estimate or identify a corresponding input or output power level of amplifier 52.

Referring back to FIG. 4, power detector 100 can output a measured value to processing circuitry 110. Processing circuitry 110 can represent processing circuitry 18 within control circuitry 14 of FIG. 1, processing circuitry 24 of FIG. 2, or other processing component within device 10. Processing circuitry 110 can analyze the measure value received from power detector 100 and output corresponding control signals to amplifier 52 via control path 112. As an example, processing circuitry 110 can be configured to run one or more algorithms for determining optimum controls signals for dynamically tuning amplifier 52 based on the received measured value(s). As another example, processing circuitry 110 can use the received measured value(s) for referring to a lookup table (LUT) to determine optimum control signals for dynamically tuning amplifier 52. As another example, processing circuitry 110 can employ a neural network or other machine-learning-based subsystem to determine suitable control signals for dynamically tuning amplifier 52 based on the received measured value(s). These examples are illustrative.

In general, processing circuitry 110 can output control signals over path 112 to control one or more bias parameters of amplifier 52 (e.g., to control one or more bias voltage, bias point, or other biasing configuration for amplifier 52). Processing circuitry 110 can additionally or alternatively output control signals over path 112 to control an impedance matching circuit of amplifier 52 (e.g., to tune an input matching circuit of amplifier 52 and/or an output matching circuit of amplifier 52). The input and/or output matching circuits of amplifier 52 can generally include one or more adjustable capacitors, one or more adjustable inductors, one or more adjustable resistors, and/or other adjustable components that can be tuned by processing circuitry 110. Processing circuitry 110 can generally control amplifier 52 to provide improved linearity while avoiding operation in the saturation region/mode.

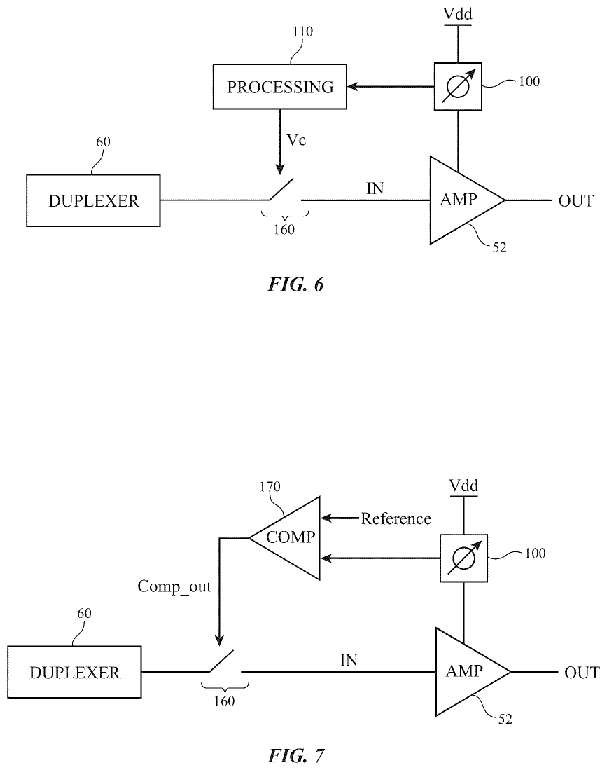

The embodiment of FIG. 4 in which processing circuitry 110 is configured to control components within amplifier 52 based on measured values is exemplary. FIG. 6 shows another embodiment in which processing circuitry 110 is configured to control a switch such as switch 160 coupled at the input of amplifier 52. Switch 160 is sometimes referred to as an amplifier input switch. As shown in FIG. 6, processing circuitry 110 may receive a measured value from power detector 100 and can output a corresponding control signal Vc for controlling switch 160. For example, if processing circuitry 110 receives measured values indicative of input power levels exceeding a certain power threshold, then processing circuitry 110 may output signal Vc that deactivates switch 160. Deactivating switch 160 in this way can be beneficial to protect amplifier 52 from receiving input signals that would otherwise damage amplifier 52. When processing circuitry 110 receives measured values indicative of input power levels below the power threshold, then processing circuitry 110 may output signal Vc that activates switch 160.

The term “activate” with respect to a switch (or transistor) may refer to or be defined herein as an action that places the switch in an “on” or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

The embodiment of FIG. 6 in which the amplifier input switch 160 is controlled by processing circuitry 110 (e.g., one or more baseband processor) is exemplary. FIG. 7 shows another embodiment in which a comparator circuit such as comparator 170 is configured to control switch 160 coupled at the input of amplifier 52. Comparator 170 can be considered part of control circuitry 14 of FIG. 1. As shown in FIG. 7, comparator 170 may have a first input configured to receive measured values from power detector 100, a second input configured to receive a reference signal (e.g., a signal representing a power threshold level), and an output on which a comparator output signal Comp_out is generated.

The comparator output signal Comp_out can be used to control switch 160. For example, if comparator 170 receives measured values that are greater than the reference signal (e.g., indicative of an excessively high input power level), then comparator 170 may output a low signal Comp_out that deactivates switch 160. Deactivating switch 160 in this way can be beneficial to protect amplifier 52 from receiving input signals that would otherwise damage amplifier 52. When comparator 170 receives measured values that are less than the reference signal (e.g., indicative of an acceptable input power level), then comparator 170 may output a high signal Comp_out that activates switch 160. Configured in this way, comparator 170 can deactivate switch 160 when the measured current values output from power detector 100 are outside a defined range of values. Compared to the embodiment of FIG. 6, using comparator 170 to control switch 160 may provide reduced tuning latency.

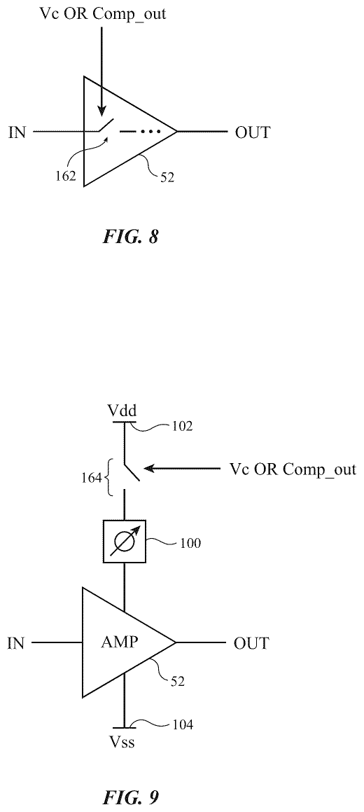

The embodiments of FIGS. 6 and 7 in which switch 160 external to amplifier 52 is being controlled based on measured values from power detector 100 are exemplary. FIG. 8 shows another embodiment in which a switch such as switch 162 within amplifier 52 is being controlled by signal Vc (e.g., the control signal output from processing circuitry 110 as described in connection with FIG. 6) or signal Comp_out (e.g., the comparator output signal produced from comparator 170 as described in connection with FIG. 7). Switch 162 can be an input transistor within amplifier 52. Switch 162 can generally represent one or more transistors within amplifier 52. When signals Vc and Comp_out exhibit a first value, switch 162 may be activated. When signal Vc and Comp_out exhibit a second value different than the first value, switch 162 may be deactivated. Controlling one or more switches 162 within amplifier 52 in this way can help prevent amplifier 52 from being damaged in response to detecting receipt of a high power signal at amplifier 52.

FIG. 9 shows another example in which a switch such as switch 164 coupled in the power supply path is being controlled by signal Vc (e.g., the control signal output from processing circuitry 110 as described in connection with FIG. 6) or signal Comp_out (e.g., the comparator output signal produced from comparator 170 as described in connection with FIG. 7). Switch 164 can be coupled in series with power detector 100. Switch 164 can be coupled between power supply line 102 and power detector 100. Alternatively, power detector 100 can be coupled between power supply line 102 and switch 164. Switch 164 being coupled to the power supply terminal of amplifier 52 is sometimes referred to as a “power supply switch.” When signals Vc and Comp_out exhibit a first value, switch 164 may be activated. When signal Vc and Comp_out exhibit a second value different than the first value, switch 164 may be deactivated. Controlling one or more power supply switches 164 associated with amplifier 52 in this way can help prevent amplifier 52 from being damaged in response to detecting receipt of a high power signal at amplifier 52. Additionally or alternatively, amplifier 52 can optionally be provided with ground power supply switches that are controlled by signal Vc or Comp_out (e.g., power supply switches for selectively decoupling amplifier 52 from the ground power supply line).

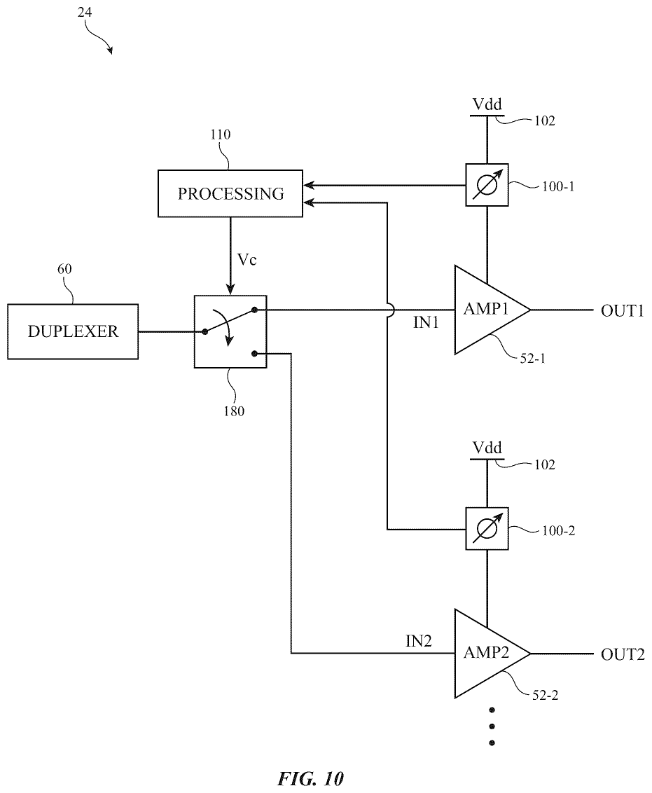

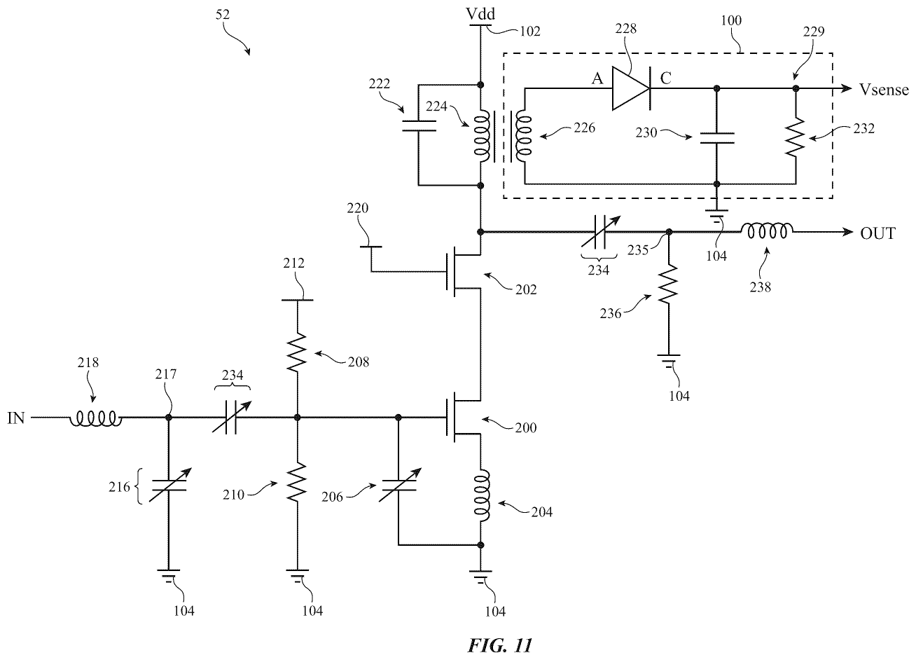

The embodiments of FIGS. 4-9 that describe controlling components associated with amplifier 52 are illustrative. FIG. 10 shows another embodiment in which processing circuitry 110 is configured to select from among a plurality of amplifiers based on measured values. As shown in FIG. 10, wireless circuitry 24 may include a first amplifier 52-1 and a second amplifier 52-2 coupled to duplexer 60 via switch 180. As an example, amplifier 52-1 may be an amplifier designed for low power consumption, whereas amplifier 52-2 may be an amplifier designed for high linearity. In general, amplifiers 52-1 and 52-2 can be separately optimized for different modes of radio-frequency operation. Amplifier 52-1 can be measured using power detector 100-1 (e.g., power detector 100-1 can be configured to measure an amount of supply current drawn by amplifier 52-1). Amplifier 52-2 can be measured using power detector 100-2 (e.g., power detector 100-2 can be configured to measure an amount of supply current drawn by amplifier 52-2).

The measured values obtained from power detectors 100-1 and 100-2 can be conveyed to processing circuitry 110. Based on the received measured values, processing circuitry 110 can control switch 180. When amplifier 52-1 is switched into use, power detector 100-1 will output measured values to processing circuitry 110. When processing circuitry 110 receives measured values from power detector 100-1 that are within a first range of values, processing circuitry 110 can maintain switch 180 at its current state so that any received signals are being fed to the input of amplifier 52-1. When processing circuitry 110 receives measured values from power detector 100-1 that are outside the first range of values, processing circuitry 110 can toggle switch 180 so that any received signals are instead fed to the input of amplifier 52-2.

When amplifier 52-2 is switched into use, power detector 100-2 will output measured values to processing circuitry 110. When processing circuitry 110 receives measured values from power detector 100-2 within a second range of values, processing circuitry 110 can maintain switch 180 at its current state so that any received signals are being fed to the input of amplifier 52-2. When processing circuitry 110 receives measured values from power detector 100-2 that are outside the second range of values, processing circuitry 110 can toggle switch 180 so that any received signals are instead fed to the input of amplifier 52-1.

The example of FIG. 10 in which processing circuitry 110 is configured to switch between at least two different amplifiers 52 based on measured current values is illustrative. In other embodiments, processing circuitry 110 can optionally be configured to switch among three or more amplifiers 52 or four or more amplifiers 52 based on the measured current values. In yet other embodiments, processing circuitry 110 can be configured to selectively activate a subset of amplifier stages within an amplifier 52. For example, consider a scenario in which an amplifier 52 includes two or more amplifier stages connected in a chain. Based on the measured current values output from an associated power detector, processing circuitry 110 can selectively activate a subset of the amplifier stages within amplifier 52 (e.g., some of the stages in the amplifier chain), all of the amplifier stages within amplifier 52, or can deactivate all of the amplifier stages within amplifier 52.

FIG. 11 is a circuit diagram of an illustrative amplifier 52 with a transformer-based power detector (measurement circuit) 100. As shown in FIG. 11, amplifier 52 may include an input transistor 200 and a cascode transistor 202, both optionally implemented as n-type or n-channel metal-oxide-semiconductor (NMOS) transistors. Input transistor 200 has a gate terminal, a source terminal coupled to ground line 104 via source inductor 204, and a drain terminal coupled to cascode transistor 202. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal).

An adjustable capacitor 206 can have a first terminal coupled to the gate terminal of input transistor 200 and a second terminal coupled to ground 104. A first bias resistor 208 may be coupled between a power supply line 212 (e.g., a voltage line on which a bias voltage or a power supply voltage is provided) and the gate terminal of input transistor 200, whereas a second bias resistor 210 may be coupled between the gate terminal of input transistor 200 and ground 104. Configured in this way, bias resistor 208 and 210 can be configured to provide a suitable bias voltage at the gate terminal of input transistor 200. An adjustable series capacitor 214 can be coupled between the gate terminal of transistor 200 and a node 217. An adjustable capacitor 216 can be coupled between node 217 and ground 104. A series inductor 218 may be coupled between node 217 and the input terminal IN of amplifier 52. At least some of components 206, 214, 216, and 218 coupled at the input terminal are considered part of an input (impedance) matching circuit of amplifier 52.

Cascode transistor 202 can have a source terminal coupled to input transistor 200, a gate terminal coupled to a voltage line 220 (e.g., a volage line on which a cascode bias voltage or a power supply voltage is provided), and a drain terminal. Cascode transistor 202 is optional and can be omitted. An adjustable capacitor 234 may have a first terminal coupled to the drain terminal of cascode transistor 202 and a second terminal coupled to node 235. Resistor 236 can have a first terminal coupled to node 235 and a second terminal coupled to ground 104. Inductor 238 can have a first terminal coupled to node 235 and a second terminal coupled to the output terminal OUT of amplifier 52. At least some of components 234, 236, and 238 coupled at the output terminal are considered part of an output (impedance) matching circuit of amplifier 52. An LC tank that includes capacitor 222 and inductor 224 can be coupled to the drain terminal of cascode transistor 202. In particular, inductor 224 can have a first terminal coupled cascode transistor 202 and a second terminal coupled to power supply line 102. Capacitor 222 may be coupled in parallel with inductor 224.

Power detector 100 can include an inductor 226, a diode 228, a capacitor 230, and resistor 232. Inductor 226 may be inductively coupled to inductor 224 of the LC tank. Arranged in this way, inductors 224 and 226 can be configured to operate as a transformer (e.g., inductor 224 is the primary coil/winding, whereas inductor 226 is the secondary coil/winding). Operated in this way, any AC (alternating current) current flowing through the LC tank of amplifier 52 can be mirrored onto secondary coil 226. Power detector 100 of this type is thus sometimes referred to and defined herein as a transformer-based power detector or measurement circuit. The transformer that includes coils 224 and 226 can sometimes be considered part of power detector 100. Inductor 226 can have a first terminal coupled to an anode terminal of diode 228 and a second terminal coupled to ground 104. Capacitor 230 can have a first terminal coupled to a cathode terminal of diode 228 and a second terminal coupled to ground 104. Resistor 232 can be coupled across capacitor 230. The cathode terminal of diode 228 can be coupled to a power detector output node 229.

Configured in this way, a corresponding measured (sensed) voltage Vsense is produced at output node 229. Voltage Vsense can be referred to as a measured voltage, a sensor output signal, or a power detector output signal. Voltage Vsense may be indicative of an amount of AC current being drawn by the input transistor 200 of amplifier 52 from the power supply line 102. Voltage Vsense can be conveyed to processing circuitry 110 or comparator 170 (see, e.g., FIGS. 4, 6, 7, and 10). Based on a voltage level of Vsense, processing circuitry 110 or comparator 170 can output a corresponding control signal for dynamically tuning the input matching circuit of amplifier 52 (e.g., for adjusting one or more of capacitors 206, 214, and 216), for dynamically tuning the output matching circuit of amplifier 52 (e.g., for adjusting capacitor 234 and optionally resistor 236), and/or for dynamically tuning one or more bias settings for amplifier 52 (e.g., to adjust a voltage level on voltage line 212 and/or 220).

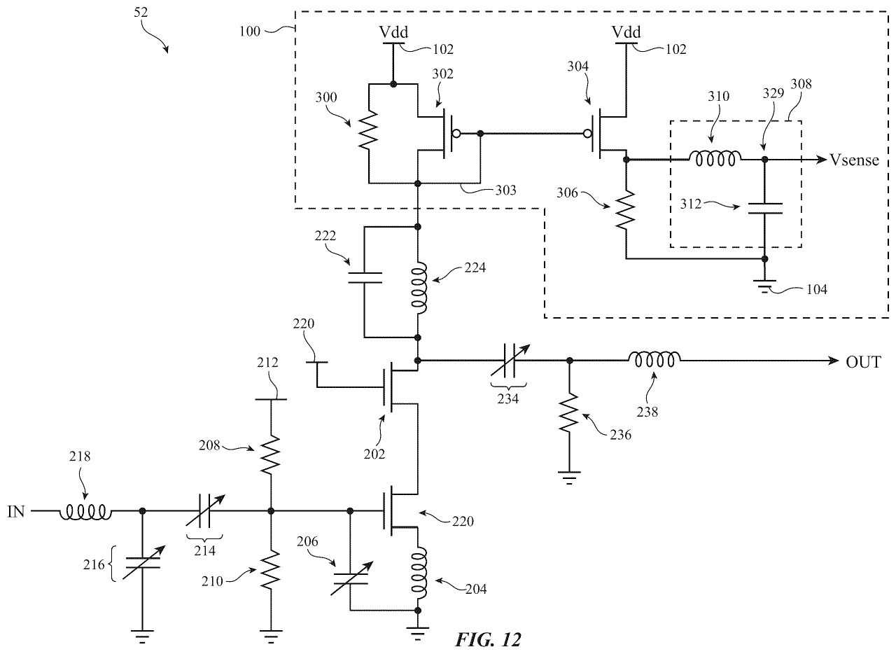

The embodiment of FIG. 11 in which amplifier 52 is coupled to a transformer-based power detector is illustrative. FIG. 12 shows another embodiment in which amplifier 52 is coupled to current-mirror-based power detector 100. The circuitry at the input side and the output side of amplifier 52 is substantially similar to that already described in connection with FIG. 11 and need not be reiterated to avoid obscuring the present embodiment. In contrast to the arrangement of FIG. 11 where the LC tank is coupled to the power detector via a transformer, the power detector 100 of FIG. 12 includes current mirroring components coupled in series with the LC tank.

As shown in FIG. 12, power detector 100 can include a resistor 300 coupled in series with the LC tank between power supply line 102 and the cascode transistor 202. A p-type transistor such as transistor 302 may be coupled in parallel with resistor 300. Transistor 302 may be a p-channel metal-oxide-semiconductor or PMOS transistor. Transistor 302 may have a source terminal coupled to power supply line 102, a drain terminal coupled to the LC tank, and a gate terminal that is shorted to its source terminal (e.g., via diode connection path 303).

Power detector 100 may further include p-type transistor 304 (e.g., a PMOS transistor), a resistor 306, an inductor 310, and a capacitor 312. At least transistors 302 and 304 arranged in the way shown in FIG. 12 are sometimes referred to collectively as a current mirror circuit.

Transistor 304 may have a source terminal coupled to power supply line 102, a gate terminal coupled to the gate terminal of transistor 302, and a drain terminal coupled to ground 104 via resistor 306. Inductor 310 may have a first terminal coupled to the drain terminal of transistor 304 and a second terminal coupled to a power detector output node 329. Capacitor 312 may be coupled across output node 329 and ground 104. Inductor 310 and capacitor 312 arranged in this way can form a low pass filter 308 for filtering AC components.

Configured in this way, the current drawn through resistor 300 and transistor 302 can be mirrored to transistor 304, and a corresponding measured (sensed) voltage Vsense is produced at output node 329. Voltage Vsense can be referred to as a measured voltage, a sensor output signal, or a power detector output signal. Voltage Vsense may be indicative of an amount of DC (direct current) current being drawn by input transistor 200 of amplifier 52 from the power supply line 102. If desired, low pass filter 308 can optionally be omitted, and voltage Vsense could be indicative of an amount of DC+AC current that is currently being drawn by amplifier 52 from power supply line 102. Voltage Vsense can be conveyed to processing circuitry 110 or comparator 170 (see, e.g., FIGS. 4, 6, 7, and 10). Based on a voltage level of Vsense, processing circuitry 110 or comparator 170 can output a corresponding control signal for dynamically tuning the input matching circuit of amplifier 52 (e.g., for adjusting one or more of capacitors 206, 214, and 216), for dynamically tuning the output matching circuit of amplifier 52 (e.g., for adjusting capacitor 234 and optionally resistor 236), and/or for dynamically tuning one or more bias settings for amplifier 52 (e.g., to adjust a voltage level on voltage line 212 and/or 220).

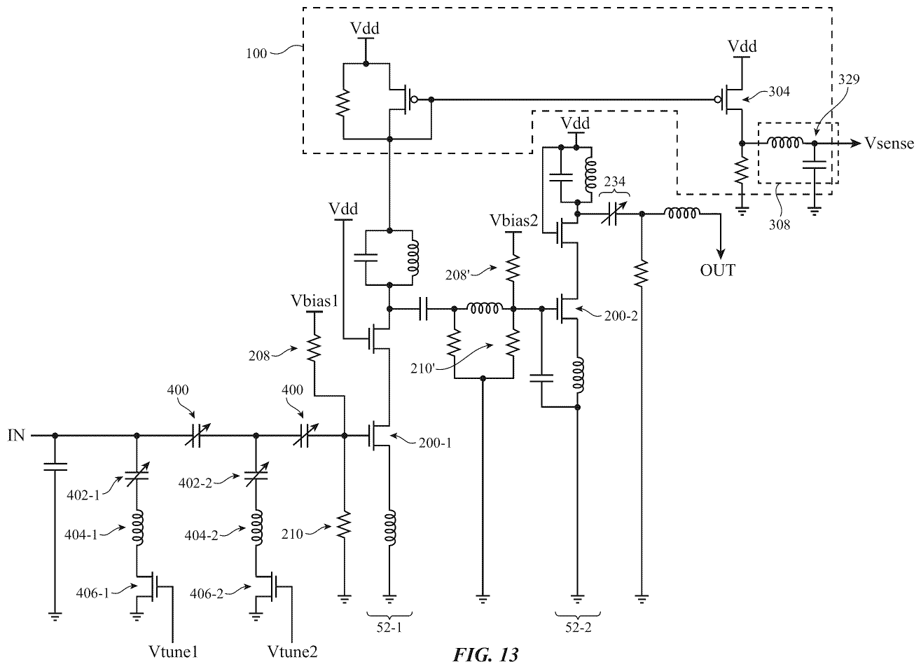

The embodiment of FIG. 12 in which the current-mirror-based power detector 100 is coupled to a single-stage amplifier 52 is illustrative. FIG. 13 shows another embodiment of amplifier circuitry that includes at least a first amplifier (stage) 52-1 and a second amplifier (stage) 52-1 connected in a chain. In particular, input transistor 200-1 of the first amplifier 52-1 may have a gate terminal coupled to adjustable series capacitors 400, adjustable shunt capacitors 402-1 and 402-2, and bias resistors 208 and 210 (e.g., bias resistors coupled to a first bias voltage Vbias1). Capacitor 402-1 may be coupled in series with inductor 404-1 and a transistor 406-1. Transistor 406-1 (e.g., an n-type or NMOs transistor) can be configured to receive a first tuning (control) signal Vtune1. Capacitor 402-2 may be coupled in series with inductor 404-2 and a transistor 406-2. Transistor 406-2 (e.g., an n-type or NMOs transistor) can be configured to receive a second tuning (control) signal Vtune2. The input transistor 200-2 of the second amplifier 52-2 may have a gate terminal coupled to, among other components, bias resistors 208′ and 210′ (e.g., bias resistors coupled to a second bias voltage Vbias2). Amplifier 52-2 may have an output that is coupled to, among other components, adjustable capacitor 234.

Power detector 100 may be coupled to the power supply terminal of the first amplifier 52-1. Configured in this way, the power supply current drawn by amplifier 52-1 can be mirrored to transistor 304 of the current mirror, and a corresponding measured (sensed) voltage Vsense can be produced at output node 329. Voltage Vsense may be indicative of an amount of DC current being drawn by amplifier 52 from the power supply line 102. If desired, low pass filter 308 can optionally be omitted, and voltage Vsense could be indicative of an amount of DC+AC current that is currently being drawn by amplifier 52-1 from power supply line 102. Voltage Vsense can be conveyed to processing circuitry 110 or comparator 170 (see, e.g., FIGS. 4, 6, 7, and 10). Based on a voltage level of Vsense, processing circuitry 110 or comparator 170 can output a corresponding control signal for dynamically tuning the input matching circuit of amplifier 52-1 (e.g., for adjusting one or more of capacitors 400, 402-1, and 404-2), for dynamically tuning the output matching circuit of amplifier 52-2 (e.g., for adjusting capacitor 234 and optionally resistor 236), and/or for dynamically tuning one or more bias settings for amplifier 52 (e.g., to adjust a voltage level of Vbias1, Vbias2, Vtune1, and/or Vtune2).

The transformed-based current sensing topology of the type described in connection with FIG. 11 and the current-mirrored-based current sensing topology of the type described in connection with FIGS. 12 and 13 are illustrative. If desired, other types of current sensing, voltage sensing, or power sensing schemes can be employed for monitoring the power level of one or more amplifier stages within wireless circuitry 24. Although most the techniques disclosed herein are described in the context of receiving amplifiers 52, the techniques can similarly be adapted to controlling transmitting amplifier 50 or any type of amplifier circuitry in a transmit or receive path.

The methods and operations described above in connection with FIGS. 1-13 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Wireless circuitry comprising:
an amplifier configured to receive a radio-frequency signal;
a measurement circuit coupled to a power supply terminal of the amplifier and configured to output a measured value; and
control circuitry configured to adjust one or more components associated with the amplifier based on the measured value output from the measurement circuit.

2. The wireless circuitry of claim 1, wherein the control circuitry is further configured to adjust an input matching circuit of the amplifier based on the measured value, and wherein the input matching circuit comprises one or more adjustable capacitors.

3. The wireless circuitry of claim 1, wherein the control circuitry is further configured to adjust an output matching circuit of the amplifier based on the measured value, and wherein the output matching circuit comprises one or more adjustable capacitors.

4. The wireless circuitry of claim 1, wherein the control circuitry is further configured to adjust one or more bias voltages of the amplifier based on the measured value.

5. The wireless circuitry of claim 1, wherein the control circuitry comprises a comparator having a first input configured to receive the measured value from the measurement circuit, a second input configured to receive a reference value, and an output coupled to the one or more components associated with the amplifier.

6. The wireless circuitry of claim 1, wherein the one or more components being adjusted by the control circuitry comprises a switch coupled to an input of the amplifier, wherein the switch is activated by the control circuitry in response to the measured value being in a range of values, and wherein the switch is deactivated by the control circuitry in response to the measured value being outside the range of values.

7. The wireless circuitry of claim 1, wherein the one or more components being adjusted by the control circuitry comprises a power supply switch coupled to a power supply terminal of the amplifier, and wherein the power supply switch is selectively activated and deactivated by the control circuitry based on the measured value.

8. The wireless circuitry of claim 1, wherein the measurement circuit is configured to measure an amount of current drawn by the amplifier.

9. The wireless circuitry of claim 1, wherein the measurement circuit comprises:
a transformer coupled to the amplifier; and
a diode coupled to the transformer.

10. The wireless circuitry of claim 1, wherein the measurement circuit comprises:
a current mirror circuit coupled to the amplifier; and
and a low pass filter coupled to the current mirror circuit.

11. The wireless circuitry of claim 1, wherein the measurement circuit comprises:
a current mirror circuit coupled to the amplifier; and
a resistor coupled to the current mirror circuit.

12. Circuitry comprising:
an input transistor;
an input matching circuit coupled to a gate terminal of the input transistor;
an inductor coupled in series with the input transistor; and
a current measurement circuit electrically coupled to at least the inductor and configured to produce an output signal for tuning the input matching circuit.

13. The circuitry of claim 12, further comprising:
bias resistors coupled to the gate terminal of the input transistor and configured to receive a bias voltage that is tuned based on the output signal of the current measurement circuit.

14. The circuitry of claim 12, further comprising:
a capacitor coupled across the inductor; and
a cascode transistor having a source terminal coupled to the input transistor, a drain terminal coupled to the inductor and the capacitor, and a gate terminal configured to receive a bias voltage that is tuned based on the output signal of the current measurement circuit.

15. The circuitry of claim 12, further comprising:
an output matching circuit directly coupled to the inductor and tuned based on the output signal of the current measurement circuit.

16. The circuitry of claim 12, wherein the current measurement circuit comprises:
a capacitor coupled across the inductor;
a transformer coupled to the capacitor, wherein the transformer comprises the inductor and an additional inductor; and
a diode coupled to the additional inductor of the transformer, wherein the output signal represents an AC (alternating current) current drawn by the input transistor.

17. The circuitry of claim 12, wherein the current measurement circuit comprises:
a capacitor coupled across the inductor;
a current mirror circuit coupled to the inductor and the capacitor;
a resistor coupled to the current mirror circuit; and
a low pass filter coupled to the current mirror circuit, wherein output signal represents a DC (direct current) current drawn by the input transistor.

18. Circuitry comprising:
a first amplifier;
a second amplifier;
a power detector coupled to a power supply terminal of the first amplifier and configured to output a measured value; and
control circuitry configured to control the first and second amplifiers based on the measured value output from the power detector.

19. The circuitry of claim 18, further comprising:
an additional power detector coupled to a power supply terminal of the second amplifier and configured to output a measured value that is conveyed to the control circuitry; and
a switch coupled to an input of the first amplifier and to an input of the second amplifier, wherein the control circuitry is configured to control the switch based on the measured values output from the power detector and the additional power detector.

20. The circuitry of claim 18, further comprising:
an input matching circuit coupled to an input of the first amplifier; and
an output matching circuit coupled to an output of the second amplifier, wherein:
the second amplifier is coupled to an output of the first amplifier;
the first amplifier has a first input transistor configured to receive a first bias voltage;
the second amplifier has a second input transistor configured to receive a second bias voltage; and
the control circuitry is further configured to adjust one or more of the input matching circuit, the output matching circuit, the first bias voltage, and the second bias voltage based on the measured value output from the power detector.
